(19) United States
(12) Patent Application Publication
(10) Pub. No.: US 2024/0234563 A9
(43) Pub. Date: Jul. 11, 2024

(54) NITRIDE SEMICONDUCTOR ELEMENT AND NITRIDE SEMICONDUCTOR DEVICE

(71) Applicant: ROHM CO., LTD., Kyoto-shi (JP)

(72) Inventor: Taojun FANG, Kyoto-shi (JP)

(73) Assignee: ROHM CO., LTD., Kyoto-shi (JP)

(21) Appl. No.: 18/488,085

(22) Filed: Oct. 17, 2023

(30) Foreign Application Priority Data
Oct. 19, 2022 (JP) 2022-167611

(51) Int. Cl. H01L 29/778; H01L 23/495; H01L 29/20; H01L 29/417; H01L 29/866

(52) U.S. Cl. CPC H01L 29/7786; H01L 23/49503; H01L 23/4952; H01L 23/49562; H01L 29/2003; H01L 29/41775; H01L 29/866

(57) ABSTRACT

The present disclosure provides a nitride semiconductor element. The nitride semiconductor element includes a semiconductor substrate having a substrate upper surface and a substrate lower surface facing opposite to the substrate upper surface, and having an active region and a peripheral region. A nitride semiconductor layer is selectively formed in the active region at the substrate upper surface to form a transistor. A source electrode and a drain electrode are in contact with the nitride semiconductor layer. A gate electrode is disposed between the source electrode and the drain electrode. A first electrode is formed on the substrate lower surface and used to electrically connect to the source electrode. The nitride semiconductor element includes a bidirectional Zener diode formed in the peripheral region and electrically connected to the first electrode.

### CROSS-REFERENCE TO RELATED APPLICATION

This application claims priority to Japanese Patent Application No. 2022-167611 filed on Oct. 19, 2022, the entire content of which is incorporated herein by reference.

### TECHNICAL FIELD

The present disclosure relates to a nitride semiconductor element and a nitride semiconductor device.

### BACKGROUND

Currently, the commercialization of high electron mobility transistors (HEMT) using group III nitride semiconductors (hereinafter sometimes referred to as “nitride semiconductors”) such as gallium nitride (GaN) is gradually in progress (for example, refer to patent document 1). A HEMT uses a two-dimensional electron gas (2DEG) formed near an interface of a semiconductor heterojunction as a conductive path (channel). Power devices using HEMTs are considered to be capable of effectuating low on-resistance and high-speed, high-frequency operations in comparison with typical silicon (Si) power devices.

### PRIOR ART DOCUMENT

### Patent Publication

[Patent document 1]: Japan Patent Publication No. 2017-73506

### BRIEF DESCRIPTION OF THE DRAWINGS

FIG. 1 is a brief plan view of a nitride semiconductor device according to a first embodiment.

FIG. 2 is a brief side view of the nitride semiconductor device in FIG. 1.

FIG. 3 is a brief cross-sectional view of the nitride semiconductor element in FIG. 1.

FIG. 4 is a brief plan view of a nitride semiconductor device according to a second embodiment.

FIG. 5 is a brief cross-sectional view of the nitride semiconductor element in FIG. 4.

FIG. 6 is a brief plan view of a nitride semiconductor device of a variation example.

FIG. 7 is a brief cross-sectional view of a nitride semiconductor element of a variation example.

FIG. 8 is a brief cross-sectional view of a nitride semiconductor element of a variation example.

FIG. 9 is a brief cross-sectional view of a nitride semiconductor element of a variation example.

FIG. 10 is a brief cross-sectional view of a nitride semiconductor element of a variation example.

FIG. 11 is a brief plan view of a nitride semiconductor device of a variation example.

### DETAILED DESCRIPTION OF THE EMBODIMENTS

Details of several embodiments of a nitride semiconductor device of the present disclosure are given with the accompanying drawings below. To keep the description clear and simple, the constituting elements shown in the drawings are not necessarily drawn to fixed scales. Moreover, for better understanding, shading lines may be omitted from the cross-sectional views. It should be noted that the drawings are for illustrating the embodiments of the present disclosure, and are not to be construed as limitations to the present disclosure. The terms “first”, “second” and “third” of the present disclosure are for distinguishing target objects, and are not intended for sorting the target objects.

The description below includes details for implementing a device, a system and a method of the exemplary embodiments of the present disclosure. The detailed description is intended for illustration purposes and is not to be construed as limitations to the embodiments of the present disclosure or applications or uses of these embodiments.

The expression “at least one” used in the present application also implies “one or more” of desired options. As an example, if the number of options is two, the expression such as “at least one” used in the present application means “only one of the options” or “both of the options”. For another example, if the number of options is three or more, the expression such as “at least one” used in the present application means “only one of the options” or “a combination of any two or more of the options”.

### First Embodiment

### (Brief Structure of Nitride Semiconductor Device)

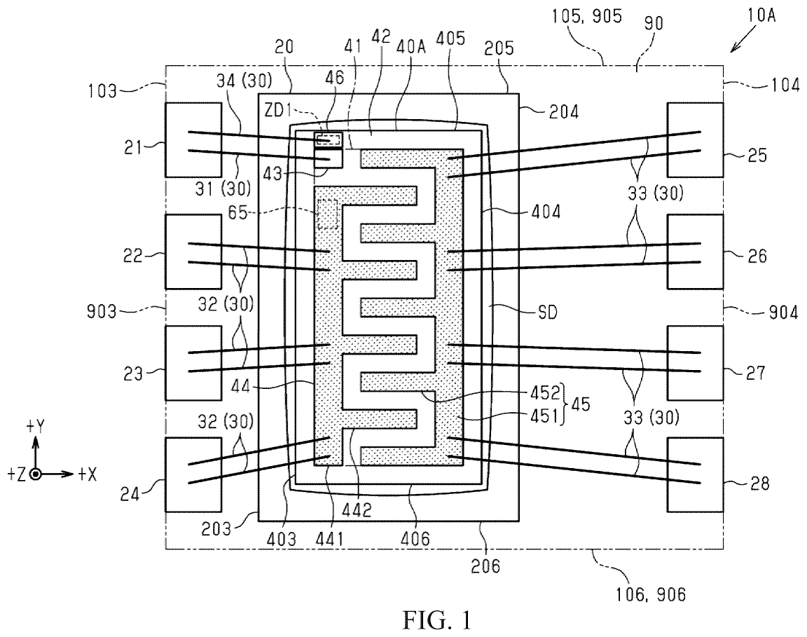

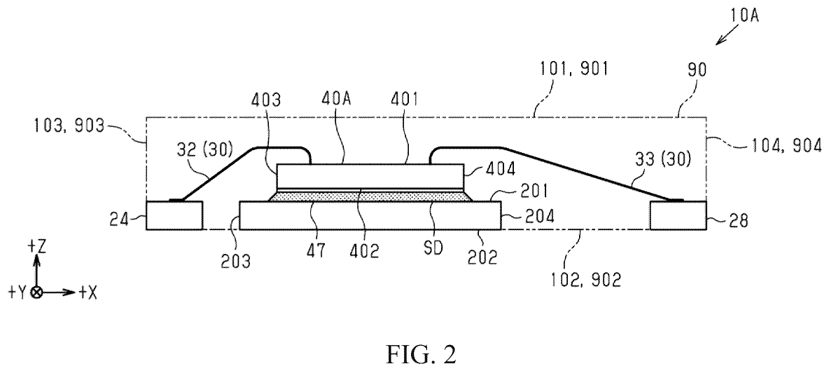

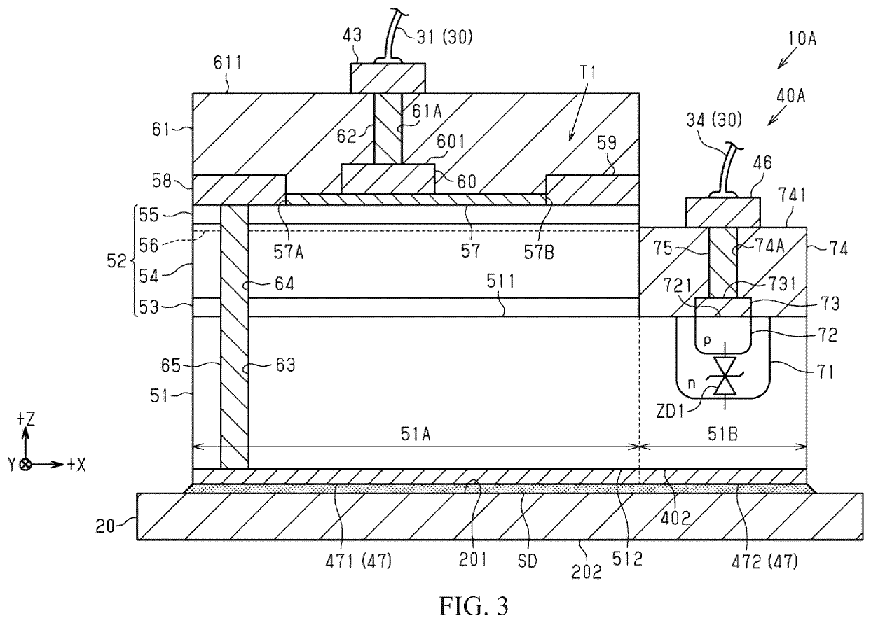

FIG. 1 shows a brief plan view of an exemplary nitride semiconductor device 10A according to a first embodiment. FIG. 2 shows a brief side view of FIG. 1. FIG. 3 shows a brief cross-sectional view of a nitride semiconductor element 40A in FIG. 1. In FIG. 1 and FIG. 2, a sealing resin 90 of the nitride semiconductor device 10A is shown by a double-dot-dashed line.

As shown in FIG. 1 and FIG. 2, the nitride semiconductor device 10A is formed as, for example, a rectangular tablet. For better illustration purposes, the thickness direction of the nitride semiconductor device 10A is set as the Z-axis direction, and the directions of two axes orthogonal to the Z-axis direction and orthogonal to each other are set as the X-axis direction and the Y-axis direction. Moreover, the expression “in a plan view” used in the present disclosure refers to observing the nitride semiconductor device 10A in the Z-axis direction shown in FIG. 1.

The nitride semiconductor device 10A includes an upper surface 101, and a lower surface 102 facing opposite to the upper surface 101. In the first embodiment, the upper surface 101 and the lower surface 102 form a rectangle longer in the X-axis direction relative to the Y-axis direction. The nitride semiconductor device 10A further includes multiple side surfaces 103, 104, 105 and 106. The side surfaces 103 to 106 are surfaces connecting the upper surface 101 and the lower surface 102, and are orthogonal to the upper surface 101 and the lower surface 102 in the first embodiment. The side surfaces 103 and 104 face to sides opposite to each other in the X-axis direction. The side surfaces 105 and 106 face to sides opposite to each other in the Y-axis direction.

The nitride semiconductor device 10A further includes a nitride semiconductor element 40A, a die pad 20, multiple terminals 21 to 28, multiple conductive members 30, and a sealing resin 90.

The die pad 20 and the multiple terminals 21 to 28 are formed of, for example, a copper (Cu)-containing material. A plating film can also be disposed on front surfaces of the die pad 20 and the terminals 21 to 28. The plating film is, for example, silver (Ag) plating, or nickel (Ni)/palladium (Pd)/gold (Au) plating. The die pad 20 and the multiple terminals 21 to 28 for formed by, for example, a lead frame.

For example, the die pad 20 is formed as a rectangular tablet. The die pad 20 includes an upper surface 201, and a lower surface 202 facing opposite to the upper surface 201. The upper surface 201 and the lower surface 202 are rectangular in a plan view. The die pad 20 is arranged to have its lengthwise side along the Y-axis direction. The die pad 20 further includes multiple side surfaces 203, 204, 205 and 206. The side surfaces 203 to 206 are surfaces connecting the upper surface 201 and the lower surface 202. The side surfaces 203 to 206 are surfaces orthogonal to both the upper surface 201 and the lower surface 202 in the first embodiment. The side surfaces 203 and 204 face to sides opposite to each other in the X-axis direction. The side surfaces 205 and 206 face to sides opposite to each other in the Y-axis direction.

The multiple terminals 21 to 28 are arranged along the side surfaces 103 and 104 of the nitride semiconductor device 10A. The terminals 21 to 24 are arranged along the side surface 103. Each of the terminals 21 to 24 is exposed from the side surface 103 and the lower surface 102. The terminals 25 to 28 are arranged along the side surface 104. Each of the terminals 25 to 28 is exposed from the side surface 104 and the lower surface 102. Each of the terminals 21 to 28 is a terminal for mounting the nitride semiconductor device 10A on such as a circuit substrate. In the first embodiment, the terminal 21 is a gate terminal, and the terminals 22 to 24 are source terminals. Moreover, in FIG. 1, the terminals 22 to 24 are spaced in the Y-axis direction, but the terminals 22 to 24 can also be electrically connected. The terminals 25 to 28 are drain terminals. Moreover, in FIG. 1, the terminals 25 to 28 are spaced in the Y-axis direction, but the terminals 25 to 28 can also be electrically connected.

The nitride semiconductor element 40A is formed as, for example, a rectangular tablet. The nitride semiconductor element 40A includes an element upper surface 401, and an element lower surface 402 facing opposite to the element upper surface 401. The element upper surface 401 and the element lower surface 402 are rectangular in a plan view. In the first embodiment, the nitride semiconductor element 40A is arranged to have its lengthwise side along the Y-axis direction. The nitride semiconductor element 40A further includes multiple element side surfaces 403, 404, 405 and 406. The element side surfaces 403 to 406 are surfaces connecting the element upper surface 401 and the element lower surface 402. The element side surfaces 403 to 406 are surfaces orthogonal to both the element upper surface 401 and the element lower surface 402 in the first embodiment. The element side surfaces 403 and 404 face to sides opposite to each other in the X-axis direction. The element side surfaces 405 and 406 face to sides opposite to each other in the Y-axis direction.

The nitride semiconductor element 40A has the element lower surface 402 face the die pad 20 and is mounted on the die pad 20. The nitride semiconductor element 40A is bonded to the upper surface 201 of the die pad 20 via a bonding material SD. The bonding material SD is a conductive bonding material such as solder paste or silver (Ag) paste.

The nitride semiconductor element 40A includes an active region 41 and a peripheral region 42. The active region 41 is rectangular in a plan view. The peripheral region 42 includes at least a portion of a region between the active region 41 and the element side surfaces 403 to 406. In the first embodiment, the peripheral region 42 is formed in a frame shape and surrounds the active region 41 in a plan view.

The nitride semiconductor element 40A includes a high electron mobility transistor (HEMT) employing a nitride semiconductor. The HEMT is formed in the active region 41. The nitride semiconductor element 40A includes a gate pad 43, a source pad 44, a drain pad 45 and a connection pad 46 on the element upper surface 401, as external connection terminals of the nitride semiconductor element 40A. The gate pad 43, the source pad 44 and the drain pad 45 are disposed in the active region 41.

The source pad 44 can also include a source body 441 and a source extension portion 442. The source body 441 is formed to extend along the element side surface 403 of the nitride semiconductor element 40A in a plan view. The source body 441 is rectangular in a plan view. The source extension portion 442 is formed to extend from the source body 441 in a direction crossing the source body 441, more specifically, orthogonal to the source body 441 in the first embodiment. The source pad 44 of the first embodiment includes two source extension portions 442. The two source extension portions 442 are spaced by a constant interval in between. The source pad 44 is formed in a comb shape via the source body 441 and the source extension portion 442.

The drain pad 45 can also include a drain body 451 and a drain extension portion 452. The drain body 451 is formed to extend along the element side surface 404 of the nitride semiconductor element 40A in a plan view. The drain body 451 is rectangular in a plan view. The drain extension portion 452 is formed to extend from the drain body 451 in a direction crossing the drain body 451, more specifically, orthogonal to the drain body 451 in the first embodiment. The drain pad 45 of the first embodiment includes two drain extension portions 452. The two drain extension portions 452 are spaced by a constant interval in between. The drain pad 45 is formed in a comb shape via the drain body 451 and the drain extension portion 452. The drain pad 45 is arranged to be comb-engaged with the source pad 44.

The gate pad 43 is rectangular in a plan view. The gate pad 43 is configured on one corner of the active region 41 in a plan view. The gate pad 43 is arranged on an extension line in an extension direction of the source body 441 and on an extension line in an extension direction of the drain extension portion 452. In an example, the gate pad 43 is arranged on an extension line of the source body 441 along the element side surface 403 and on an extension line of the drain extension portion 452 along the element side surface 405. Moreover, multiple gate pads 43 can be disposed. For example, the gate pad 43 can also be disposed on an extension line of the source body 441 and on an extension line of the drain extension portion 452 along the element side surface 406.

The connection pad 46 is arranged in the peripheral region 42. In the first embodiment, the connection pad 46 is arranged on a position adjacent to the gate pad 43. In the first embodiment, the connection pad 46 is rectangular in a plan view.

The nitride semiconductor element 40A is electrically connected to the terminals 21 to 28 via the multiple conductive members 30. The conductive member 30 is, for example, a bonding wire. The bonding wire can be implemented by, for example, materials such as Cu, Au and aluminum (Al).

The nitride semiconductor element 40A includes the gate pad 43, the source pad 44, the drain pad 45 and the connection pad 46. The conductive members 30 include conductive members 31 to 34. The gate pad 43 is electrically connected to the terminal 21 via the conductive member 31. The source pad 44 is electrically connected to the terminals 22 to 24 via the multiple conductive members 32. The drain pad 45 is electrically connected to the terminals 25 to 28 via the multiple conductive members 33. The connection pad 46 is electrically connected to the terminal 21 via the conductive member 34. That is to say, the gate pad 43 and the connection pad 46 are electrically connected to the terminal 21. The terminal 21 is electrically connected to the gate pad 43 of the nitride semiconductor element 40A via the conductive member 31. Thus, the connection pad 46 is electrically connected to the gate pad 43.

As shown in FIG. 2, the nitride semiconductor element 40A has a back electrode 47 on the element lower surface 402. The back electrode 47 is electrically connected to the source pad 44. The back electrode 47 is electrically connected to the die pad 20 via the conductive bonding material SD. Thus, in the nitride semiconductor device 10A of the first embodiment, the die pad 20 is electrically connected to the source pad 44 of the nitride semiconductor element 40A.

The sealing resin 90 seals a portion of the die pad 20 and the multiple terminals 21 to 28, the nitride semiconductor element 40A, and the conductive members 31 to 34. The sealing resin 90 is formed of an insulating resin. The sealing resin 90 is formed of, for example, black epoxy.

The sealing resin 90 is, for example, formed as a rectangular tablet.

The sealing resin 90 includes a resin upper surface 901, and a resin lower surface 902 facing opposite to the resin upper surface 901. The resin upper surface 901 and the resin lower surface 902 are rectangular in a plan view. In the first embodiment, the sealing resin 90 is formed as a rectangle having a lengthwise side along the X-axis direction. The sealing resin 90 further includes multiple resin side surfaces 903, 904, 905 and 906. The resin side surfaces 903 to 906 are surfaces connecting the resin upper surface 901 and the resin lower surface 902. The resin side surfaces 903 to 906 are surfaces orthogonal to both the resin upper surface 901 and the resin lower surface 902 in the first embodiment. The resin side surfaces 903 and 904 face to sides opposite to each other in the X-axis direction. The resin side surfaces 905 and 906 face to sides opposite to each other in the Y-axis direction. The resin upper surface 901 and the resin lower surface 902 form the upper surface 101 and the lower surface 102 of the nitride semiconductor device 10A. The multiple resin side surfaces 903 to 906 form the side surfaces 103 to 106 of the nitride semiconductor device 10A.

The lower surface 202 of the die pad 20 is exposed from the resin lower surface 902 of the sealing resin 90. In an example, the lower surface 202 of the die pad 20 and the lower surface 902 of the sealing resin 90 are located on a same plane. Each of the terminals 21 to 24 is exposed from the resin side surface 903 and the resin lower surface 902 of the sealing resin 90. Moreover, each of the terminals 21 to 24 can also be configured to be exposed from the resin lower surface 902 of the sealing resin 90 but not exposed from the resin side surface 903. Each of the terminals 25 to 28 is exposed from the resin side surface 904 and the resin lower surface 902 of the sealing resin 90. Moreover, each of the terminals 25 to 28 can also be configured to be exposed from the resin lower surface 902 of the sealing resin 90 but not exposed from the resin side surface 904.

### (Structure of Nitride Semiconductor Element)

The nitride semiconductor element 40A shown in FIG. 1 includes a high electron mobility transistor (HEMT) employing a nitride semiconductor.

As shown in FIG. 3, the nitride semiconductor element 40A includes a semiconductor substrate 51, and a nitride semiconductor layer 52 selectively formed over the semiconductor substrate 51.

The semiconductor substrate 51 includes a substrate upper surface 511, and a substrate lower surface 512 facing opposite to the substrate upper surface 511. The substrate lower surface 512 can also be configured to form the element lower surface 402 of the nitride semiconductor element 40A.

The semiconductor substrate 51 has an active region 51A and a peripheral region 51B. The active region 51A of the semiconductor substrate 51 can also overlap the active region 41 of the nitride semiconductor element 40A in FIG. 1. The peripheral region 51B of the semiconductor substrate 51 can also overlap the peripheral region 42 of the nitride semiconductor element 40A in FIG. 1.

The semiconductor substrate 51 can be implemented by, for example, a silicon (Si) substrate. The semiconductor substrate 51 can also be a silicon carbide (SiC) substrate. The semiconductor substrate 51 is a substrate of a first conductivity type. The first conductivity type is, for example, p-type, and the semiconductor substrate 51 includes an impurity of the first conductivity type (p-type).

### (Active Region)

The nitride semiconductor layer 52 is formed in the active region 51A of the semiconductor substrate 51.

The nitride semiconductor layer 52 includes a buffer layer 53 formed over the semiconductor substrate 51, an electron transit layer 54 formed over the buffer layer 53, and an electron supply layer 55 over the electron transit layer 54.

The buffer layer 53 can be formed by any material capable of inhibiting die warping or cracking caused by mismatch between thermal expansion coefficients of the semiconductor substrate 51 and the electron transit layer 54. In addition, the buffer layer 53 can further include one or more nitride semiconductor layers. For example, the buffer layer 53 can include at least one of an aluminum nitride (AlN) layer, aluminum gallium nitride (AlGaN) layer, and a grating AlGaN layer with different aluminum (Al) compositions. For example, the buffer layer 53 can be formed by one single AlN film, one single AlGaN film, a film having an AlGaN/GaN superlattice structure, a film having an AlN/AlGaN superlattice structure, or a film having an AlN/GaN superlattice structure.

In one example, the buffer layer 53 can include a first buffer layer which is an AlN layer formed on the semiconductor substrate 51, and a second buffer layer which is an AlGaN layer formed on the AlN layer (first buffer layer). For example, the first buffer layer can be an AlN layer and the second buffer layer can be a grating AlGaN layer. Moreover, to inhibit a leakage current in the buffer layer 53, an impurity can be introduced to a portion of the buffer layer 53 such that a region other than a surface-layer region of the buffer layer 53 is semi-insulative. In this case, the impurity is, for example, carbon (C) or iron (Fe).

Since the electron transit layer 54 is formed over the buffer layer 53 formed on the semiconductor layer 51, it can be said as formed above the semiconductor substrate 51 or be said as formed over the semiconductor substrate 51. The electron transit layer 54 can be a GaN layer, for example. Moreover, an impurity can be introduced to a portion of the electron transit layer 54 so as to set a region other than a surface-layer region of the electron transit layer 54 to be semi-insulative. In this case, the impurity is, for example, carbon (C). That is to say, the electron transit layer 54 can include multiple GaN layers with impurities of different concentrations, and in one example, the multiple GaN layers are a GaN layer doped with C and a non-doped GaN layer. In this case, the GaN layer doped with C is formed on the buffer layer 53.

The electron supply layer 55 is made of a nitride semiconductor having a bandgap greater than that of the electron transit layer 54. Moreover, the electron supply layer 55 can be, for example, an AlGaN layer. In the nitride semiconductor, the bandgap increases as the Al composition gets higher. Thus, the electron supply layer 55 which is an AlGaN layer has a bandgap greater than that of the electron transit layer 54 which is a GaN layer. In one example, the electron supply layer 55 is formed by AlxGal-xN. That is to say, it can be said that the electron supply layer 55 is an AlxGal-xN layer, where x is 0<x<0.4, and more preferably 0.1<x<0.3.

The electron transit layer 54 and the electron supply layer 55 have different grid constants in body regions. Thus, the electron transit layer 54 and the electron supply layer 55 form a heterojunction of a grid mismatching system. Due to spontaneous polarization of the electron transit layer 54 and the electron supply layer 55 as well as piezoelectric polarization caused by stress upon the heterojunction of the electron transit layer 54, a conduction band energy level of the electron transit layer 54 near the heterojunction interface between the electron transit layer 54 and the electron supply layer 55 is lower than a Fermi level. Thus, at a position near the heterojunction interface between the electron transit layer 54 and the electron supply layer 55 (for example, a position distanced from the interface by approximately several nm), a two-dimensional electron gas (2DEG) 56 is expanded into the electron transit layer 54.

The nitride semiconductor element 40A includes an insulating layer 57, a source electrode 58, a drain electrode 59 and a gate electrode 60.

The insulating layer 57 is formed over the nitride semiconductor layer 52. The insulating layer 57 is connected to an upper surface of the nitride semiconductor layer 52 (electron transit layer). The insulating layer 57 can also be formed of an insulative material such as SiO₂, SiN, SiON or Al₂O₃. The insulating layer 57 of the first embodiment insulates the nitride semiconductor layer 52 from the gate electrode 60, and thus can also be referred to as a gate insulating film.

The insulating layer 57 includes a source opening 57A and a drain opening 57B. The source opening 57A and the drain opening 57B pass through the insulating layer 57 up to the upper surface of the electron transit layer 54. The source opening 57A exposes a portion of the upper surface of the electron supply layer 55 as a source connection region. The drain opening 57B exposes a portion of the upper surface of the electron supply layer 55 as a drain connection region.

The source electrode 58 is in contact with the electron transit layer 54 via the source opening 57A of the insulating layer 57. The source electrode 58 is in in ohmic contact with the 2DEG 56 right below the electron supply layer 55. The drain electrode 59 is in contact with the electron transit layer 54 via the drain opening 57B of the insulating layer 57. The drain electrode 59 is in in ohmic contact with the 2DEG 56 right below the electron supply layer 55.

The source electrode 58 and the drain electrode 59 can be formed by a metal layer of at least one of a titanium (Ti) layer, a TiN layer, an Al layer, an AlSiCu layer and an AlCu layer. Moreover, the source electrode 58 and the drain electrode 59 are formed by one or more metal layers. For example, the source electrode 58 and the drain electrode 59 are formed of the same material.

The gate electrode 60 is disposed between the source electrode 58 and the drain electrode 59. The gate electrode 60 is disposed on the insulating layer 57. The gate electrode 60 can be formed by a metal layer of at least one of a Ti layer, a TiN layer, an Al layer, an AlSiCu layer and an AlCu layer. Moreover, the gate electrode 60 can be formed by one or more metal layers.

The electron transit layer 54 and the electron supply layer 55 of the nitride semiconductor layer 52, together with the source electrode 58, the drain electrode 59 and the gate electrode 60 formed over the electron supply layer 55 form a HEMT employing a nitride semiconductor. That is to say, the nitride semiconductor element 40A includes a transistor T1 formed by a HEMT.

The active region in which the transistor T1 is formed is covered by an insulating film 61. The insulating film 61 covers the insulating layer 57, the source electrode 58, the drain electrode 59 and the gate electrode 60. The insulating film 61 includes an opening 61A that exposes a portion of an upper surface 601 of the gate electrode 60. A via hole 62 is formed in the opening 61A. The via hole 62 is a through wiring passing through the insulating film 61. The via hole 62 is electrically connected to the gate electrode 60.

The gate pad 43 is formed on an upper surface 611 of the insulating film 61. The gate pad 43 is electrically connected to the via hole 62. In the first embodiment, the gate pad 43 is electrically connected to the gate electrode 60 via the via hole 62. The conductive member 31 is connected to the gate pad 43.

Moreover, although omitted from the drawings, the insulating film 61 includes openings that expose portions of upper surfaces of the source electrode 58 and the drain electrode 59. Via holes are formed in these openings. The source pad 44 and the drain pad 45 shown in FIG. 1 are formed on the upper surface 611 of the insulating film 61. The source pad 44 is electrically connected to the gate electrode 58 through the via hole. The drain pad 45 is electrically connected to the drain electrode 59 through the via hole.

The back electrode 47 is formed on the substrate lower surface 512 of the semiconductor substrate 51. The back electrode 47 includes a lower surface source electrode 471 formed corresponding to the active region 51A of the semiconductor substrate 51, and a first electrode 472 formed corresponding to the peripheral region 51B of the semiconductor substrate 51. The lower surface source electrode 471 can also be formed in a portion of the active region 51A on the substrate lower surface 512. The first electrode 472 can also be formed in a portion of the peripheral region 51B on the substrate lower surface 512.

The semiconductor substrate 51 of the first embodiment includes a through hole 63 passing through the semiconductor substrate 51 from the substrate upper surface 511 up to the substrate lower surface 512. Moreover, the nitride semiconductor layer 52 of the first embodiment includes a through hole 64 passing through the electron transit layer 54, the electron supply layer 55 and the buffer layer 53. The through hole 63 of the semiconductor substrate 51 is in communication with the through hole 64 of the nitride semiconductor layer 52 in the thickness direction (Z-axis direction) of the nitride semiconductor element 40A. The nitride semiconductor element 40A of the first embodiment includes a through electrode 65 formed in the through holes 63 and 64. The through electrode 65 passes through the nitride semiconductor layer 52 and the semiconductor substrate 51. The through electrode 65 is electrically connected to the source electrode 58 formed on the nitride semiconductor layer 52. Moreover, the through electrode 65 is electrically connected to the lower surface source electrode 471 on the substrate lower surface 512 of the semiconductor substrate 51. Thus, the lower surface source electrode 471 is electrically connected to the source electrode 58 via the through electrode 65. The through electrode 65 is equivalent to a source connection member that electrically connects the source electrode 58 to the lower surface source electrode 471. Moreover, the lower surface source electrode 471 is electrically connected to the first electrode 472. Accordingly, the first electrode 472 is electrically connected to the source electrode 58 via the lower surface source electrode 471 and the through electrode 65.

### (Peripheral Region)

The semiconductor substrate 51 includes a first region 71 formed in the peripheral region 51B and a second region 72 formed within the first region 71. The first region 71 is formed on the side of the substrate upper surface 511 in the peripheral region 51B. The second region 72 is formed within the first region 71 and on the side of the substrate upper surface 511.

The first region 71 is an impurity region including an impurity of a second conductivity type (for example, n-type), which is a second conductivity type region. The peripheral region 51B of the semiconductor substrate 51 is in pn-junction with the first region 71 to form a Zener diode. The second region 72 is an impurity region including an impurity of a first conductivity type (p-type), which is a first conductivity type region. The second region 72 is in pn-junction with the first region 71 to form a Zener diode. Accordingly, the semiconductor substrate 51 includes a bidirectional Zener diode ZD1. The bidirectional Zener diode ZD1 is formed by the peripheral region 51B of the semiconductor substrate 51, and the first region 71 and the second region 72 formed in the peripheral region 51B. Thus, it can be said that the bidirectional Zener diode ZD1 is formed in a portion of the peripheral region 51B of the semiconductor substrate 51. The bidirectional Zener diode ZD1 is formed in a thickness direction of the semiconductor substrate 51. The bidirectional Zener diode ZD1 is electrically connected to the first electrode 472 formed in the peripheral region 51B of the semiconductor substrate 51.

A second electrode 73 is formed in the peripheral region 51B of the semiconductor substrate 51. The second electrode 73 is electrically connected to the second region 72. Thus, the second electrode 73 is electrically connected to the bidirectional Zener diode ZD1 formed on the semiconductor substrate 51. Moreover, it can be said that the bidirectional Zener diode ZD1 is electrically connected between the first electrode 472 and the second electrode 73.

The peripheral region 51B is covered by the insulating film 74. The insulating film 74 covers the second electrode 73. The insulating film 74 includes an opening 74A that exposes a portion of an upper surface 731 of the second electrode 73. A via hole 75 is formed in the opening 74A. The via hole 75 is a through wiring passing through the insulating film 74. The via hole 75 is electrically connected to the second electrode 73.

The connection pad 46 is formed on an upper surface 741 of the insulating film 74. The connection pad 46 is electrically connected to the via hole 75. In the first embodiment, the connection pad 46 is electrically connected to the bidirectional Zener diode ZD1 through the via hole 75 and the second electrode 73. The conductive member 34 is connected to the connection pad 46.

The nitride semiconductor device 10A includes the transistor T1 formed by a HEMT. Thus, the nitride semiconductor element 40A of the first embodiment includes the transistor T1 which is formed by a HEMT and a bidirectional Zener diode ZD1 formed on the semiconductor substrate 51.

The bidirectional Zener diode ZD1 is electrically connected between the first electrode 472 and the second electrode 73. The first electrode 472 is electrically connected to the source electrode 58 of the transistor T1 via the lower surface source electrode 471 and the through electrode 65. The second electrode 73 is electrically connected to the connection pad 46 through the via hole 75. The connection pad 46 is electrically connected to the gate pad 43 via the conductive member 34, the terminal 21 and the conductive member 31 of the nitride semiconductor device 10A in FIG. 1. The gate pad 43 is electrically connected to the gate electrode 60 of the transistor T1 via the via hole 62.

Thus, it can be said that the entirety of the second electrode 73, or the upper surface 731 of the second electrode 73 is a connection region for connecting the bidirectional Zener diode ZD1 to the gate electrode 60. Moreover, because the upper surface 721 of the second region 72 forming the bidirectional Zener diode ZD1 is connected to the second electrode 73, it can be said that the upper surface 721 is a connection region for connecting the bidirectional Zener diode ZD1 to the gate electrode 60.

The bidirectional Zener diode ZD1 of the first embodiment is connected between the source electrode 58 and the gate electrode 60 of the transistor T1. That is to say, the nitride semiconductor device 10A of the first embodiment includes the transistor T1 which is formed by a HEMT and the bidirectional Zener diode ZD1 connected between the gate and the source of the transistor T1. For example, a current caused by electrostatic discharge (ESD) flows to the bidirectional Zener diode ZD1. Thus, the bidirectional Zener diode ZD1 inhibits an overly large current from flowing to between the gate and the source of the transistor T1. Accordingly, in the nitride semiconductor device 10A, a high ESD tolerance (for example, 2000 V or more) can be ensured.

### (Effects)

As described above, the following effects are achieved according to the first embodiment.

(1-1) The nitride semiconductor element 40A includes the semiconductor substrate 51, the nitride semiconductor layer 52, the source electrode 58, the drain electrode 59 and the gate electrode 60. The semiconductor substrate 51 includes the substrate upper surface 511, and the substrate lower surface 512 facing opposite to the substrate upper surface 511, and has the active region 51A and the peripheral region 51B. The nitride semiconductor layer 52 is selectively formed in the active region 51A at the substrate upper surface 511 of the semiconductor substrate 51 to form the transistor T1. The source electrode 58 and the drain electrode 59 are in contact with the nitride semiconductor layer 52. The gate electrode 60 is disposed between the source electrode 58 and the drain electrode 59. On the substrate lower surface 512 of the semiconductor substrate 51, the first electrode 472 for connecting to the source electrode 58 is formed. The nitride semiconductor element 40A includes the bidirectional Zener diode ZD1. The bidirectional Zener diode ZD1 is formed in the peripheral region 51B and is electrically connected to the first electrode 472. The upper surface 721 of the second region 72 that becomes the connection region is for electrically connecting the bidirectional Zener diode ZD1 to the gate electrode 60. The nitride semiconductor element 40A includes the transistor T1 which is formed by a HEMT, and the bidirectional Zener diode ZD1. The bidirectional Zener diode ZD1 is connected between the source electrode 58 and the gate electrode 60 of the transistor T1. Accordingly, in the nitride semiconductor device 10A, a high ESD tolerance can be ensured.

(1-2) The connection pad 46 is arranged adjacent to the gate pad 43. The gate pad 43 is connected to the terminal 21 via the conductive member 31. The connection pad 46 is connected to the terminal 21 via the conductive member 34. Thus, similar to the connection of the gate pad 43 and the terminal 21, the connection pad 46 can be connected to the terminal 21. Moreover, because the connection pad 46 can be easily connected to the gate pad 43, the bidirectional Zener diode ZD1 can be easily connected to the gate electrode 60 of the transistor T1.

(1-3) The nitride semiconductor element 40A includes the back electrode 47 formed on the substrate lower surface 512 of the semiconductor substrate 51. The back electrode 47 includes the first electrode 472 electrically connected to the bidirectional Zener diode ZD1, and the lower surface source electrode 471 electrically connected to the first electrode 472. Moreover, the nitride semiconductor element 40A includes the through electrode 65 electrically connected to the source electrode 58. The through electrode 65 is electrically connected to the lower surface source electrode 471. Thus, the bidirectional Zener diode ZD1 can be easily connected to the source electrode 58 of the transistor T1.

### Second Embodiment

### (Brief Structure of Nitride Semiconductor Device)

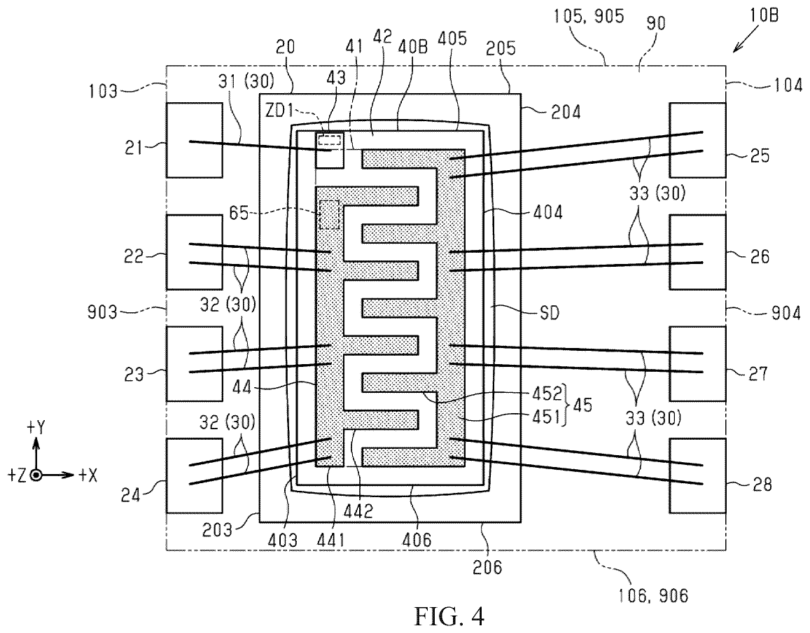

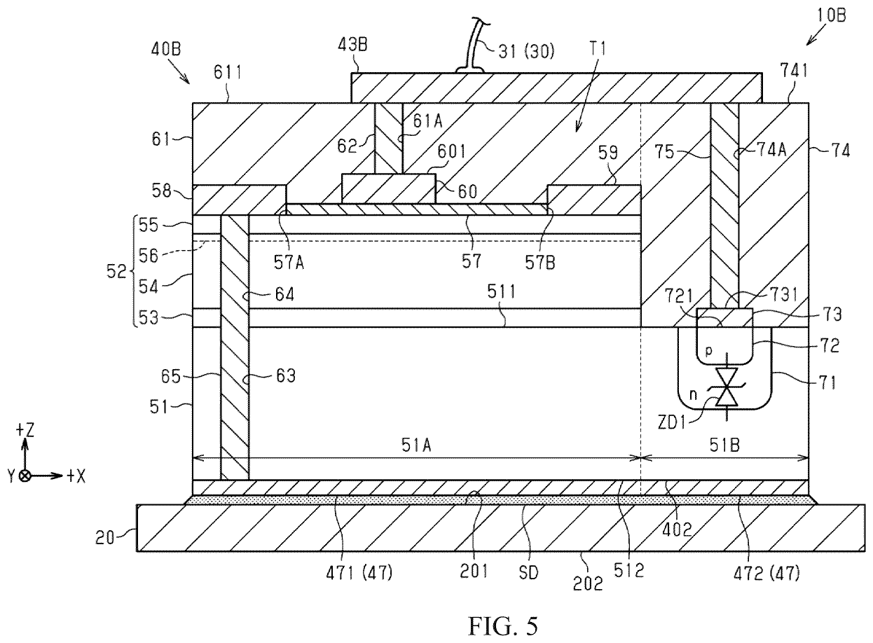

FIG. 4 shows a brief plan view of an exemplary nitride semiconductor device 10B according to a second embodiment. FIG. 5 shows a brief cross-sectional view of a nitride semiconductor element 40B in FIG. 4. In FIG. 4 and FIG. 5, constituting elements same as those of the nitride semiconductor device 10A of the first embodiment are represented by the same numerals and symbols. In the description below, associated details of the constituting elements same as those of the first embodiment are omitted for brevity, and only details of constituting elements different from those of the first embodiment are described.

As shown in FIG. 4, the nitride semiconductor device 10B of the second embodiment includes the nitride semiconductor element 40B. Moreover, in the nitride semiconductor device 10B of the second embodiment, the connection pad 46 and the conductive member 34 in the nitride semiconductor device 10A of the first embodiment are omitted.

The nitride semiconductor element 40B includes a gate pad 43B, the source pad 44 and the drain pad 45 on the element upper surface 401.

The gate pad 43B of the second embodiment is formed to extend from the active region 41 to the peripheral region 42. The nitride semiconductor element 40B includes the bidirectional Zener diode ZD1 formed in the peripheral region 42. The gate pad 43B is formed to overlap the bidirectional Zener diode ZD1 in a plan view.

As shown in FIG. 5, the nitride semiconductor element 40B includes the insulating film 74 covering the peripheral region 51B of the semiconductor substrate 51. The upper surface 741 of the insulating film 74 and the upper surface 611 of the insulating film 61 are formed on a same plane, and the insulating film 61 covers the transistor T1 formed by the nitride semiconductor layer 52 in the active region 51A of the semiconductor substrate 51. Moreover, the insulating film 74 and the insulating film 61 may also be formed integrally.

The gate pad 43B extends from the upper surface 611 of the insulating film 61 to the upper surface 741 of the insulating film 74. The via hole 75 connected to the second electrode 73 extends to the upper surface 741 of the insulating film 74. In addition, the via hole 75 is electrically connected to the gate pad 43B. Thus, the bidirectional Zener diode ZD1 of the second embodiment is electrically connected to the gate electrode 60 via the second electrode 73, the via hole 75, the gate pad 43B and the via hole 62.

The nitride semiconductor element 40B includes the second electrode 73, the via hole 75, the gate pad 43B and the via hole 62 connected between the bidirectional Zener diode ZD1 and the gate electrode 60. The upper surface 721 of the second region 72 forming the bidirectional Zener diode ZD1 is equivalent to a connection region. Moreover, the second electrode 73, the via hole 75, the gate pad 43B and the via hole 62 are equivalent to a gate connection wiring that electrically connects the gate electrode 60 to the connection region of the bidirectional Zener diode ZD1.

### (Effects)

As described above, the following effects are achieved according to the second embodiment.

(2-1) Effects the same as effects (1-1) and (1-3) of the first embodiment are achieved.

(2-2) The gate pad 43B is formed to extend from the active region 41 to the peripheral region 42. The gate pad 43B is electrically connected to the gate electrode 60 through the via hole 62. Moreover, the gate pad 43B is electrically connected to the bidirectional Zener diode ZD1 through the via hole 75 and the second electrode 73. Thus, the nitride semiconductor element 40B including the transistor T1 which is a HEMT, and the bidirectional Zener diode ZD1 connected between the gate and the source of the transistor T1, can be provided.

(2-3) The nitride semiconductor device 10B includes the nitride semiconductor element 40B. With the nitride semiconductor element 40B, the conductive member 34 connected to the connection pad 46 of the first embodiment and its connection steps can be eliminated.

### Variation Examples

The embodiments can be modified as follows. Given that no technical contradiction is resulted, the following variation examples may be used in combination. Moreover, in the variation examples below, parts that are common with the embodiments described above are denoted by the same numerals and symbols, and the related descriptions are omitted.

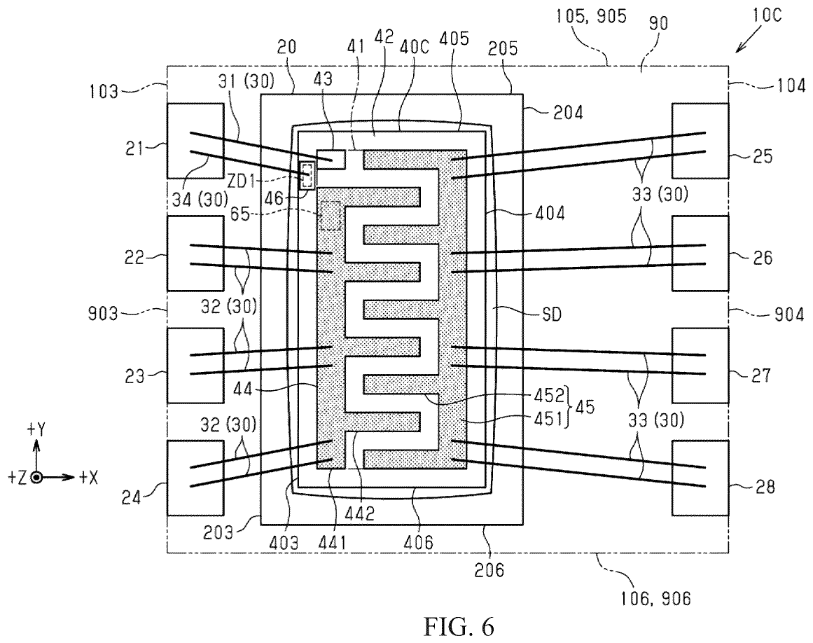

In a nitride semiconductor device 10C shown in FIG. 6, the connection pad 46 is formed in the peripheral region 42 on the element side surface 403 of the nitride semiconductor element 40C. The bidirectional Zener diode ZD1 is formed to overlap the connection pad 46 in a plan view. Moreover, in the nitride semiconductor element 40C shown in FIG. 6, the bidirectional Zener diode ZD1 can also be formed in a peripheral region along the element side surface 405.

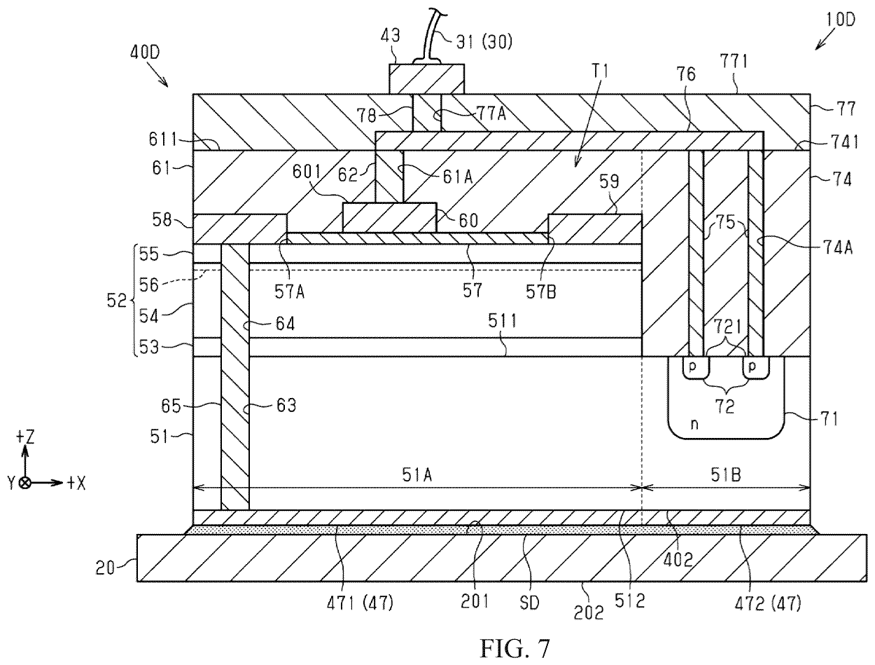

In a nitride semiconductor device 10D shown in FIG. 7, a nitride semiconductor element 40D has two second regions 72 formed within the first region 71. Moreover, three or more second regions 72 can also be formed. The two second regions 72 are respectively connected to the via holes 75. The via holes 75 extend to the upper surface 741 of the insulating film 74 covering the peripheral region 51B of the semiconductor substrate 51. In the variation example, similar to the second embodiment, the upper surface 741 of the insulating film 74 and the upper surface 611 of the insulating film 61 are formed on a same plane, and the insulating film 61 covers the transistor T1 formed by the nitride semiconductor layer 52 in the active region 51A of the semiconductor substrate 51. A gate wiring 76 is formed on the upper surface 611 of the insulating film 61. The gate wiring 76 is electrically connected to the via hole 62 of the gate electrode 60. The gate wiring 76 extends to the upper surface 741 of the insulating film 74. Moreover, the gate wiring 76 is electrically connected to the via hole 75.

In addition, the nitride semiconductor element 40D includes a second insulating film 77 that covers the insulating films 61 and 74 and the gate wiring 76. The second insulating film 77 includes an opening 77A that exposes a portion of the gate wiring 76. A via hole 78 is formed in the opening 77A. The via hole 78 is a through wiring passing through the second insulating film 77. The via hole 78 is electrically connected to the gate wiring 76. The gate pad 43 is formed on an upper surface 771 of the second insulating film 77.

The nitride semiconductor element 40D includes the via hole 75 connecting between the bidirectional Zener diode ZD1 and the gate electrode 60, the gate wiring 76 and the via hole 62. The upper surface 721 of the second region 72 forming the bidirectional Zener diode ZD1 is equivalent to a connection region. Moreover, the via hole 75, the gate wiring 76 and the via hole 62 are equivalent to a gate connection wiring that electrically connects the gate electrode 60 to the connection region of the bidirectional Zener diode ZD1.

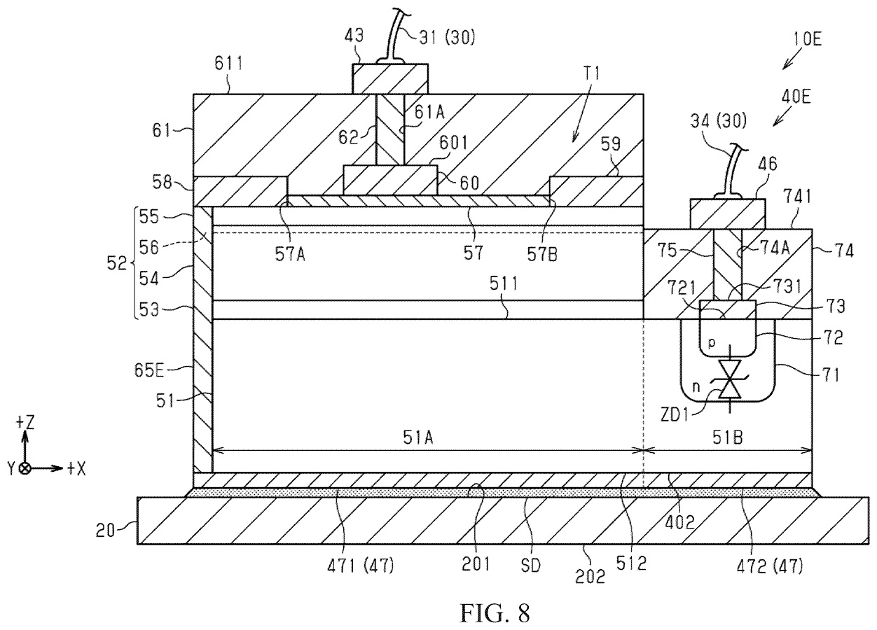

In a nitride semiconductor device 10E shown in FIG. 8, a nitride semiconductor element 40E includes a connection wiring 65E in substitution for the through electrode 65 (refer to FIG. 3). The connection wiring 65E is formed along the side surfaces of the nitride semiconductor layer 52 and the semiconductor substrate 51. As such, the connection wiring 65E electrically connects the source electrode 58 to the lower surface source electrode 471 in the nitride semiconductor element 40E.

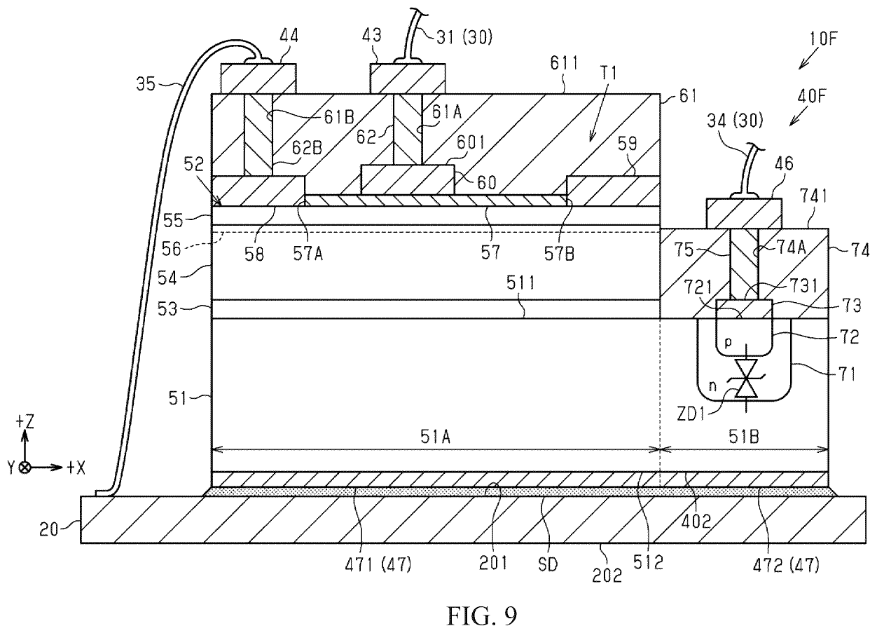

In a nitride semiconductor device 10F shown in FIG. 9, the insulating film 61 of the nitride semiconductor element 40F includes an opening 61B that exposes a portion of the source electrode 58. A via hole 62B is formed in the opening 61B. The via hole 62B is electrically connected to the source electrode 58. The source pad 44 is formed on the upper surface 611 of the insulating film 61. The source pad 44 is electrically connected to the via hole 62B.

The nitride semiconductor device 10F includes a connection member 35 connecting the source pad 44 and the die pad 20. The first electrode 472 formed on the substrate lower surface 512 of the semiconductor substrate 51 is electrically connected to the die pad 20 via the conductive bonding material SD. Thus, the bidirectional Zener diode ZD1 is connected between the source and the gate of the transistor T1 in the nitride semiconductor device 10F. Moreover, in the nitride semiconductor element 40F, only the first electrode 472 is included and the lower surface source electrode 471 can be omitted.

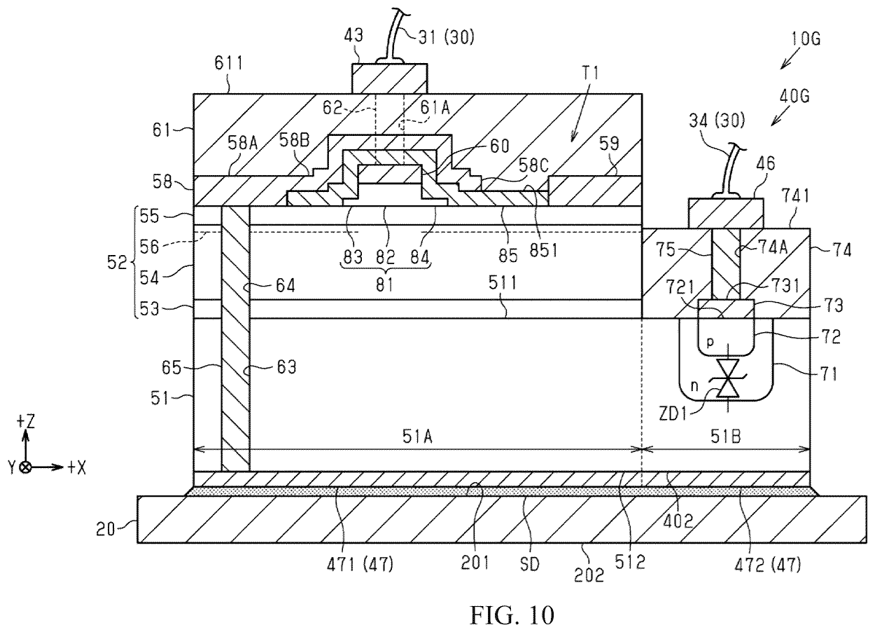

In a nitride semiconductor device 10G shown in FIG. 10, a nitride semiconductor element 40G includes a gate layer 81 formed over the electron supply layer 55, and a gate electrode 60 form over the gate layer 81.

The gate layer 81 has a bandgap less than that of the electron supply layer 55, and is formed by a nitride semiconductor containing an impurity of an acceptor type. The gate layer 81 can be formed by, for example, an AlGaN layer, which is any material having a bandgap less than that of the electron supply layer 55. In one example, the gate layer 81 is a GaN layer doped with an impurity of an acceptor type (p-type GaN layer). The impurity of an acceptor type can include at least one of magnesium (Mg), zinc (Zn) and C. The nitride semiconductor element 40G expands toward the semiconductor substrate 51 to a depletion layer of the nitride semiconductor layer 52 via the gate layer 81 including the impurity of an acceptor type, and a channel right below the gate layer 81 disappears, such that the transistor T1 acts as a normally off transistor T1.

The gate layer 81 can have a stepped structure. In one example, the gate layer 81 includes a ridge 82, and a source side step 83 and a drain side step 84 respectively extending in opposite directions from both sides of the ridge 82. The ridge 82, the source side step 83 and the drain side step 84 form the stepped structure of the gate layer 81.

The ridge 82 is equivalent to a thicker portion of the gate layer 81. The gate electrode 60 is in contact with the upper surface 721 of the ridge 82. The gate electrode 60 and the gate layer 81 form a Schottky junction. A cross section of the ridge 82 can be shaped as a rectangular shape or a stepped shape.

The source side step 83 extends from the ridge 82 to the source electrode 58. The drain side step 84 extends from the ridge 82 to the drain electrode 59. The drain side step 84 extends from the ridge 82 farther than the source side step 83. However, the source side step 83 ad the drain side step 84 can also have the same length.

The nitride semiconductor element 40G further includes a passivation layer 85. The passivation layer 85 covers the electron supply layer 55, the gate layer 81 and the gate electrode 60. The passivation layer 85 can be formed by any material selected from SiO₂, SiN, SiON, Al₂O₃, AlN and AlON. In one example, the passivation layer 85 is formed by a material including SiO₂.

The source electrode 58 can include a source electrode portion 58A, and a source field plate portion 58B that is continuous with the source electrode portion 58A. The source electrode portion 58A is in electrically connected to the electron supply layer 55. The source field plate portion 58B and an upper region of the source electrode portion 58A are formed integrally, and are formed on an upper surface 851 of the passivation layer 85 to cover the entirety of the gate layer 81 in a plan view.

The source field plate portion 58B has an end portion 58C near the drain electrode 59. The end portion 58C is located between the drain electrode 59 and the gate electrode 60 in a plan view. When a high voltage is applied between the source and the drain while a voltage between the source and the drain is 0 V, a depletion layer of the source field plate portion 58B extends out toward 2DEG 56 right below the source field plate portion 58B, achieving an effect of alleviating electric field concentration near an end portion of the gate electrode 60 and an end portion of the gate layer 81.

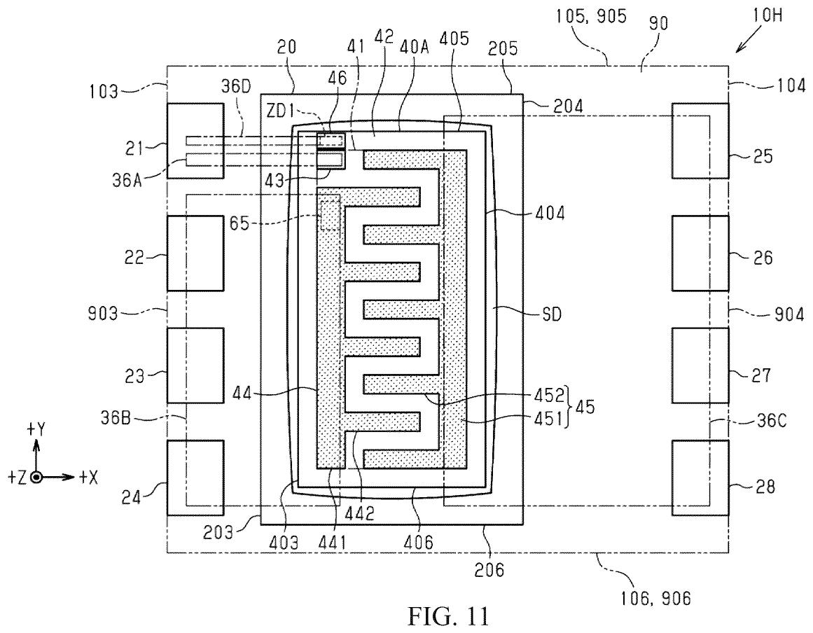

A nitride semiconductor device 10H shown in FIG. 11 includes conductive members 36A, 36B, 36C and 36D connecting the nitride semiconductor element 40A, and the terminals 21 to 28. Moreover, in order to easily understand a position relation of the nitride semiconductor element 40A, the conductive members 36A to 36D are represented by double-dot dashed lines in FIG. 11. The conductive members 36A to 36D are formed as, for example, so-called fixtures in a form of plates. The conductive members 36A to 36D are implemented by, for example, materials such as Cu, Au and aluminum (Al). The conductive member 36A electrically connects the gate pad 43 to the terminal 21. The conductive member 36B electrically connects the source pad 44 to the terminals 22 to 24. The conductive member 36C electrically connects the drain pad 45 to the terminals 25 to 28. The conductive member 36D electrically connects the connection pad 46 to the terminal 21. By using the conductive members 36A to 36D, a low resistance and a large current can be achieved in comparison with the situation in which the conductive members 31 to 34 are formed by bonding wires. Moreover, the gate pad 43 and the connection pad 46 can also be electrically connected to the terminal 21 by one conductive member (fixture). In FIG. 11, each of the conductive members 36A to 36D is rectangular (rectangle in shape), but can also be in any shape.

In the present application, the expression “at least one of A and B” should be understood as “only A, or only B, or both of A and B”.

The terms such as “on” used in the present application also includes meanings of “over” and “above”, unless otherwise specified. Thus, the expression “a first layer formed on a second layer” can refer to that the first layer is in contact with the second layer and directly arranged on the second layer in some embodiments, or can refer to that the first layer is not in contact with the second layer and is configured over or above the second layer. That is to say, the expression “on” does not eliminate a structure having another layer between the first layer and the second layer.

The directional and spatial terms “vertical”, “horizontal”, “above”, “below”, “up/top”, “down/bottom”, “front”, “back”, “longitudinal”, “lateral”, “left”, “right”, “before” and “behind” are determined on the basis of specific orientations of devices in the description and the drawings. In the present disclosure, various orientations can be used in substitution, and thus these directional terms are not to be narrowly interpreted.

For example, the Z-axis direction used in the present disclosure is not necessarily a vertical direction, and is not necessarily completely consistent with the vertical direction. For example, the X-axis direction can be the vertical direction, or the Y-axis direction can be the vertical direction.

### (Notes)

The technical concepts encompassed by the present disclosure are recoded in the description below. Moreover, to help to better understanding rather than forming limitations, the constituting elements described in the notes are given with the same reference numerals or symbols of the corresponding constituting elements in the embodiments. The numerals or symbols are used as examples for understanding purposes, and the constituting elements described in the notes are not limited to be construed as constituting elements indicated by the numerals or symbols.

### (Note 1)

A nitride semiconductor element, comprising:
a semiconductor substrate (51), including a substrate upper surface (511) and a substrate lower surface (512) facing opposite to the substrate upper surface (511), and including an active region (51A) and a peripheral region (51B);
a nitride semiconductor layer (52), selectively formed in the active region (51A) at the substrate upper surface (511) to form a transistor (T1);
a source electrode (58) and a drain electrode (59), in contact with the nitride semiconductor layer (52);
a gate electrode (60), disposed between the source electrode (58) and the drain electrode (59);
a first electrode (472), formed on the substrate lower surface (512) and configured to electrically connect to the source electrode (58);
a bidirectional Zener diode (ZD1), formed in the peripheral region (51B) and electrically connected to the first electrode (472); and
a connection region (721, 73, 731), configured to electrically connect the bidirectional Zener diode (ZD1) to the gate electrode (60).

### (Note 2)

The nitride semiconductor element of Note 1, wherein the semiconductor substrate (51) is of a first conductivity type (p), and the bidirectional Zener diode (ZD1) includes:
a first region (71) of a second conductivity type formed in the peripheral region (51B) on the substrate upper surface (511); and
a second region (72) of the first conductivity type formed within the first region (71).

### (Note 3)

The nitride semiconductor element of Note 1 or 2, further comprising:
a gate connection wiring (62, 76, 75) electrically connecting the gate electrode (60) to the connection region (721).

### (Note 4)

The nitride semiconductor element of any one of Notes 1 to 3, further comprising:
a second electrode (73) formed in the peripheral region (51B) on the substrate upper surface (511) and electrically connected to the bidirectional Zener diode (ZD1), wherein the connection region is an upper surface (731) of the second electrode (73).

### (Note 5)

The nitride semiconductor element of any one of Notes 1 to 4, further comprising:
a gate pad (43) formed on the active region (41, 51A) and electrically connected to the gate electrode (60), wherein
the peripheral region (51B) is disposed at least at a position adjacent to the gate pad, and the bidirectional Zener diode (ZD1) is formed in the peripheral region (51B) and adjacent to the gate pad in a plan view.

### (Note 6)

The nitride semiconductor element of any one of Notes 1 to 4, further comprising:
a gate pad (43) formed on the active region (41, 51A) and electrically connected to the gate electrode (60), wherein
the peripheral region (42, 51B) is formed in a frame shape and surrounds the active region (41, 51A), and the bidirectional Zener diode (ZD1) is formed in a portion of the peripheral region (42, 51B).

### (Note 7)

The nitride semiconductor element of Note 5 or 6, further comprising:
a connection pad (46) formed on the peripheral region (51B), wherein the connection region (721, 73, 731) is electrically connected to the connection pad (46).

### (Note 8)

The nitride semiconductor element of Note 7, wherein the connection pad (46) is arranged adjacent to the gate pad (43).

### (Note 9)

The nitride semiconductor element of Note 5 or 6, wherein the connection region (721, 73, 731) is connected to the gate pad (43).

### (Note 10)

The nitride semiconductor element of Note 9, wherein
the gate pad (43) is formed to overlap the bidirectional Zener diode (ZD1) in a plan view.

### (Note 11)

The nitride semiconductor element of any one of Notes 1 to 10, wherein
the nitride semiconductor layer (52) includes a buffer layer (53), an electron transit layer (54) over the buffer layer (53), and an electron supply layer (55) over the electron transit layer (54).

### (Note 12)

The nitride semiconductor element of Note 11, further comprising:
an insulating layer (57) formed on a portion of the electron supply layer (55) between the source electrode (58) and the drain electrode (59), wherein the gate electrode (60) is disposed on the insulating layer (57).

### (Note 13)

The nitride semiconductor element of Note 11, further comprising:
a gate layer (81) disposed on a portion of the electron supply layer (55) between the source electrode (58) and the drain electrode (59), wherein the gate electrode (60) is disposed on the gate layer.

### (Note 14)

The nitride semiconductor element of any one of Notes 1 to 13, wherein
the first electrode (472) is disposed in the peripheral region (51B) on the substrate lower surface (512).

### (Note 15)

The nitride semiconductor element of any one of Notes 1 to 14, further comprising:
a lower surface source electrode (58) disposed in the active region (51A) on the substrate lower surface (512).

### (Note 16)

The nitride semiconductor element of Note 15, further comprising:
a source connection member (65, 65E) electrically connecting the source electrode (58) to the lower surface source electrode (58).

### (Note 17)

The nitride semiconductor element of Note 15 or 16, wherein the lower surface source electrode (58) is electrically connected to the first electrode (472).

### (Note 18)

A nitride semiconductor device, comprising:
a nitride semiconductor element (40A to 40G), including an element front surface (401) and an element back surface (402), and a source pad (44), a drain pad (45) and a gate pad (43) disposed on the element front surface (401);
a die pad (20), on which the nitride semiconductor element (40A to 40G) is mounted;
a sealing resin (90), sealing the nitride semiconductor element (40A to 40G) and the die pad (20); and
a source terminal (22 to 24), a drain terminal (25 to 28) and a gate terminal (21), arranged around the die pad (20) and exposed from the sealing resin (90), wherein the nitride semiconductor element (40A to 40G) includes:
   a semiconductor substrate (51), including a substrate upper surface (511) and a substrate lower surface (512) facing opposite to the substrate upper surface (511), and including an active region (51A) and a peripheral region (51B);
   a nitride semiconductor layer (52), selectively formed in the active region (51A) at the substrate upper surface (511) to form a transistor (T1);
   a source electrode (58) and a drain electrode (59), in contact with the nitride semiconductor layer (52);
   a gate electrode (60), disposed between the source electrode (58) and the drain electrode (59);
   a first electrode (472), formed on the substrate lower surface (512) and configured to electrically connect to the source electrode (58);
   a bidirectional Zener diode (ZD1), formed in the peripheral region (51B) and electrically connected to the first electrode (472); and
   a connection member (73, 76, 46, 34, 31), configured to electrically connect the bidirectional Zener diode (ZD1) to the gate electrode.

### (Note 19)

The nitride semiconductor device of Note 18, wherein the connection member includes a through wiring (75) connecting the bidirectional Zener diode (ZD1) to the gate pad.

### (Note 20)

The nitride semiconductor device of Note 18 or 19, wherein the connection member includes:
a connection pad (46), disposed on the element front surface (401) and connected to the bidirectional Zener diode (ZD1); and
a wire (31, 34), connecting the connection pad (46) to the gate pad (43).

It should be noted that the description above is just simple examples. It can be conceivable to a person skilled in the art that, apart from the constituting elements and methods (manufacturing processes) enumerated in the technical details of the present disclosure, there are many other conceivable combinations and substitutions. The present disclosure is intended to encompass all substitutions, modifications and variations covered by the scope of claims of the present disclosure.

1. A nitride semiconductor element, comprising:
a semiconductor substrate, including a substrate upper surface and a substrate lower surface facing opposite to the substrate upper surface, and including an active region and a peripheral region;
a nitride semiconductor layer, selectively formed in the active region at the substrate upper surface to form a transistor;
a source electrode and a drain electrode, in contact with the nitride semiconductor layer;
a gate electrode, disposed between the source electrode and the drain electrode;
a first electrode, formed on the substrate lower surface and configured to electrically connect to the source electrode;
a bidirectional Zener diode, formed in the peripheral region and electrically connected to the first electrode; and
a connection region, configured to electrically connect the bidirectional Zener diode to the gate electrode.

2. The nitride semiconductor element of claim 1, wherein
the semiconductor substrate is of a first conductivity type, and
the bidirectional Zener diode includes:
a first region of a second conductivity type formed in the peripheral region on the substrate upper surface; and
a second region of the first conductivity type formed within the first region.

3. The nitride semiconductor element of claim 1, further comprising a gate connection wiring electrically connecting the gate electrode to the connection region.

4. The nitride semiconductor element of claim 1, further comprising a second electrode formed in the peripheral region on the substrate upper surface and electrically connected to the bidirectional Zener diode, wherein the connection region is an upper surface of the second electrode.

5. The nitride semiconductor element of claim 1, further comprising a gate pad formed on the active region and electrically connected to the gate electrode, wherein
the peripheral region is disposed at least at a position adjacent to the gate pad, and
the bidirectional Zener diode is formed in the peripheral region and adjacent to the gate pad in a plan view.

6. The nitride semiconductor element of claim 1, further comprising a gate pad formed on the active region and electrically connected to the gate electrode, wherein
the peripheral region is formed in a frame shape and surrounds the active region, and
the bidirectional Zener diode is formed in a portion of the peripheral region.

7. The nitride semiconductor element of claim 5, further comprising a connection pad formed on the peripheral region, wherein the connection region is electrically connected to the connection pad.

8. The nitride semiconductor element of claim 7, wherein the connection pad is arranged adjacent to the gate pad.

9. The nitride semiconductor element of claim 5, wherein the connection region is connected to the gate pad.

10. The nitride semiconductor element of claim 9, wherein the gate pad is formed to overlap the bidirectional Zener diode in a plan view.

11. The nitride semiconductor element of claim 1, wherein the nitride semiconductor layer includes:
a buffer layer;
an electron transit layer over the buffer layer; and
an electron supply layer over the electron transit layer.

12. The nitride semiconductor element of claim 11, further comprising an insulating layer formed on the electron supply layer, wherein the gate electrode is disposed on the insulating layer.

13. The nitride semiconductor element of claim 11, further comprising a gate layer disposed on a portion of the electron supply layer between the source electrode and the drain electrode, wherein the gate electrode is disposed on the gate layer.

14. The nitride semiconductor element of claim 1, wherein the first electrode is disposed in the peripheral region on the substrate lower surface.

15. The nitride semiconductor element of claim 1, further comprising a lower surface source electrode disposed in the active region on the substrate lower surface.

16. The nitride semiconductor element of claim 15, further comprising a source connection member electrically connecting the source electrode to the lower surface source electrode.

17. The nitride semiconductor element of claim 15, wherein the lower surface source electrode is electrically connected to the first electrode.

18. A nitride semiconductor device, comprising:
a nitride semiconductor element, including:
an element front surface and an element back surface; and
a source pad, a drain pad and a gate pad disposed on the element front surface;
a die pad, on which the nitride semiconductor element is mounted;
a sealing resin, sealing the nitride semiconductor element and the die pad; and
a source terminal, a drain terminal and a gate terminal, arranged around the die pad and exposed from the sealing resin, wherein the nitride semiconductor element includes:
a semiconductor substrate, including a substrate upper surface and a substrate lower surface facing opposite to the substrate upper surface, and including an active region and a peripheral region;
a nitride semiconductor layer, selectively formed in the active region at the substrate upper surface to form a transistor;
a source electrode and a drain electrode, in contact with the nitride semiconductor layer;
a gate electrode, disposed between the source electrode and the drain electrode;
a first electrode, formed on the substrate lower surface and configured to electrically connect to the source electrode;
a bidirectional Zener diode, formed in the peripheral region and electrically connected to the first electrode; and
a connection member, configured to electrically connect the bidirectional Zener diode to the gate electrode.

19. The nitride semiconductor device of claim 18, wherein the connection member includes a through wiring connecting the bidirectional Zener diode to the gate pad.

20. The nitride semiconductor device of claim 18, wherein the connection member includes:
a connection pad, disposed on the element front surface and connected to the bidirectional Zener diode; and
a wire, connecting the connection pad to the gate pad.
